(19) United States
(12) Patent Application Publication
(10) Pub. No.: US 2018/0163323 A1
(43) Pub. Date: Jun. 14, 2018

(54) METHOD FOR PRODUCING GROUP 13 NITRIDE SINGLE CRYSTAL AND APPARATUS FOR PRODUCING GROUP 13 NITRIDE SINGLE CRYSTAL

(71) Applicants: Takashi Satoh, Miyagi (JP); Naoya Miyoshi, Miyagi (JP); Junichi Wada, Miyagi (JP); Masahiro Hayashi, Miyagi (JP); Seiji Sarayama, Miyagi (JP); Haruo Sunakawa, Tokyo (JP); Yujirou Ishihara, Tokyo (JP); Akira Usui, Toride (JP)

(72) Inventors: Takashi Satoh, Miyagi (JP); Naoya Miyoshi, Miyagi (JP); Junichi Wada, Miyagi (JP); Masahiro Hayashi, Miyagi (JP); Seiji Sarayama, Miyagi (JP); Haruo Sunakawa, Tokyo (JP); Yujirou Ishihara, Tokyo (JP); Akira Usui, Toride (JP)

(21) Appl. No.: 15/891,764

(22) Filed: Feb. 8, 2018

Related U.S. Application Data
(63) Continuation of application No. PCT/JP2016/069138, filed on Jun. 28, 2016.

(30) Foreign Application Priority Data
Aug. 10, 2015 (JP) 2015-158489

(51) Int. Cl. C30B 29/40; C30B 19/04; C30B 19/06; C30B 19/10; C30B 17/00; C30B 35/00

(52) U.S. Cl. CPC C30B 29/403; C30B 19/04; C30B 35/007; C30B 19/106; C30B 17/00; C30B 19/06

(57) ABSTRACT

A method for producing a group 13 nitride single crystal includes dissolving and crystal growing. The dissolving includes dissolving nitrogen in a mixed melt in a reaction vessel that contains the mixed melt, a seed crystal, and a surrounding member. The mixed melt contains an alkali metal and a group 13 metal. The seed crystal is a seed crystal that is placed in the mixed melt and includes a group 13 nitride crystal in which a principal face is a c-plane. The surrounding member is arranged so as to surround the entire area of a side face of the seed crystal. The crystal growing includes growing a group 13 nitride crystal on the seed crystal.

### CROSS-REFERENCE TO RELATED APPLICATIONS

This application is a continuation of PCT international Application Ser. No. PCT/JP2016/069138, filed on Jun. 28, 2016, which designates the United States and which claims the benefit of priority from Japanese Patent Application No. 2015-158489, filed on Aug. 10, 2015; the entire contents of which are incorporated herein by reference.

### BACKGROUND OF THE INVENTION

### 1. Field of the Invention

The present invention relates to a method for producing a group 13 nitride single crystal and an apparatus for producing a group 13 nitride single crystal.

### 2. Description of the Related Art

Disclosed as a method for producing a GaN substrate using a liquid phase growth method is a flux method that dissolves nitrogen in a mixed melt of metallic sodium and metallic gallium to grow a GaN crystal. In a method for producing a group 13 nitride single crystal using the flux method, mainly a plate-shaped seed crystal with a c-plane as a principal face is used as a seed crystal.

The group 13 nitride single crystal produced by crystal growth from the seed crystal using the flux method may contain cracks. Under the circumstance, attempts are being made to produce the group 13 nitride single crystal with cracks inhibited. Japanese Unexamined Patent Application Publication No. 2008-290929 discloses that a self-supporting substrate of the same composition as that of a group III nitride-based compound semiconductor to be obtained is used as a seed crystal in order to inhibit the occurrence of cracks, for example.

However, it is difficult to reduce cracks by the conventional producing method.

### SUMMARY OF THE INVENTION

According to one aspect of the present invention, a method for producing a group 13 nitride single crystal includes dissolving and crystal growing. The dissolving includes dissolving nitrogen in a mixed melt in a reaction vessel that contains the mixed melt, a seed crystal, and a surrounding member. The mixed melt contains an alkali metal and a group 13 metal. The seed crystal is a seed crystal that is placed in the mixed melt and includes a group 13 nitride crystal in which a principal face is a c-plane. The surrounding member is arranged so as to surround the entire area of a side face of the seed crystal. The crystal growing includes growing a group 13 nitride crystal on the seed crystal.

### BRIEF DESCRIPTION OF THE DRAWINGS

FIG. 1A is an illustrative diagram of a group 13 nitride single crystal produced using a conventional producing method;

FIG. 1B is an illustrative diagram of the group 13 nitride single crystal produced using the conventional producing method;

FIG. 2 is a diagram of an example of an apparatus for producing a group 13 nitride single crystal in an embodiment of the present invention;

FIG. 3A is an illustrative diagram of an example of a surrounding member;

FIG. 3B is an illustrative diagram of the example of the surrounding member;

FIG. 3C is an illustrative diagram of the example of the surrounding member;

FIG. 4A is an illustrative diagram of an example of the surrounding member;

FIG. 4B is an illustrative diagram of the example of the surrounding member;

FIG. 5A is an illustrative diagram of an example of the surrounding member;

FIG. 5B is an illustrative diagram of the example of the surrounding member;

FIG. 5C is an illustrative diagram of the example of the surrounding member;

FIG. 5D is an illustrative diagram of the example of the surrounding member;

FIG. 6A is an illustrative diagram of an example of the surrounding member;

FIG. 6B is an illustrative diagram of the example of the surrounding member;

FIG. 6C is an illustrative diagram of the example of the surrounding member;

FIG. 7A is an illustrative diagram of an example of the surrounding member;

FIG. 7B is an illustrative diagram of the example of the surrounding member;

FIG. 8 is a photographed image of a group 13 nitride single crystal produced in an Example;

FIG. 9 is a photographed image of the group 13 nitride single crystal produced in an Example;

FIG. 10 is a photographed image of the group 13 nitride single crystal produced in an Example;

FIG. 11A is a photographed image of the group 13 nitride single crystal produced in a comparative example; and

FIG. 11B is a photographed image of the group 13 nitride single crystal produced in the comparative example.

The accompanying drawings are intended to depict exemplary embodiments of the present invention and should not be interpreted to limit the scope thereof. Identical or similar reference numerals designate identical or similar components throughout the various drawings.

### DESCRIPTION OF THE EMBODIMENTS

The terminology used herein is for the purpose of describing particular embodiments only and is not intended to be limiting of the present invention.

As used herein, the singular forms “a”, “an” and “the” are intended to include the plural forms as well, unless the context clearly indicates otherwise.

In describing preferred embodiments illustrated in the drawings, specific terminology may be employed for the sake of clarity. However, the disclosure of this patent specification is not intended to be limited to the specific terminology so selected, and it is to be understood that each specific element includes all technical equivalents that have the same function, operate in a similar manner, and achieve a similar result.

An embodiment of the present invention will be described in detail below with reference to the drawings.

In the following description, the drawings illustrate the shape, size, and arrangement of components only schematically to the extent that the invention can be understood and do not limit the present invention in a particular manner. Similar components illustrated in a plurality of drawings are denoted by the same symbols, and a redundant description thereof may be omitted.

In the following, a method for producing a group 13 nitride single crystal according to an embodiment of the present invention may be described simply referred to as a producing method according to an embodiment of the present invention.

In a method for producing a group 13 nitride single crystal according to an embodiment of the present invention, a group 13 nitride crystal is grown from a seed crystal to produce a group 13 nitride single crystal by a flux method.

A method for producing according to an embodiment of the present invention includes a dissolution process and a crystal growth process.

The dissolution process is a process in which nitrogen is dissolved in a mixed melt in a reaction vessel that contains the mixed melt, a seed crystal, and a surrounding member. The mixed melt contains an alkali metal and a group 13 metal. The seed crystal is a group 13 nitride crystal that is placed within the mixed melt and in which its principal face is a c-plane. The surrounding member is arranged so as to surround the entire area of a side face of the seed crystal. The side face of the seed crystal is a face of outer wall faces forming the seed crystal other than the c-plane as the principal face and a bottom face opposite to (substantially parallel to) the principal face.

The crystal growth process is a process for growing the group 13 nitride crystal on the seed crystal.

In a method for producing a group 13 nitride single crystal according to an embodiment of the present invention, in crystal growth using a flux method, a group 13 nitride crystal is grown in a reaction vessel that contains a seed crystal with the c-plane as the principal face, a surrounding member arranged so as to surround the entire area of the side face of the seed crystal, and a mixed melt.

Consequently, an embodiment of the present invention can reduce cracks in the group 13 nitride single crystal.

A reason why the above effect can be produced is inferred as follows. The following inference does not limit the present invention.

The surrounding member is arranged so as to cover the entire area of the side face of the seed crystal with the c-plane as the principal face, thereby inhibiting {10-11} growth of the group 13 nitride crystal that grows from the seed crystal. Consequently, it is considered that the group 13 nitride single crystal with cracks inhibited can be easily produced.

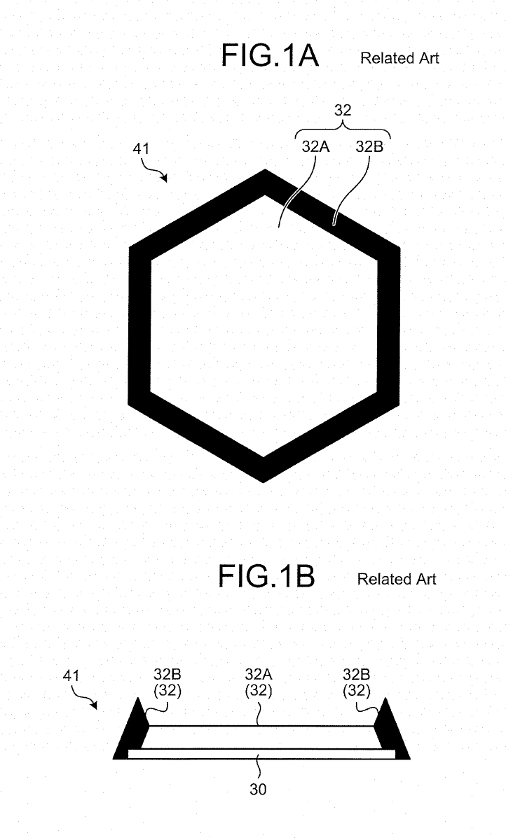

FIG. 1A and FIG. 1B are illustrative diagrams of a group 13 nitride single crystal 41 obtained by growing the group 13 nitride crystal from a seed crystal 30 with the c-plane as the principal face by a flux method using a conventional producing method. FIG. 1A is a plan view when the group 13 nitride single crystal 41 is viewed from the c-plane side of the seed crystal 30. FIG. 1B is a sectional view of the group 13 nitride single crystal 41.

The inventors of the present invention have discovered that when the group 13 nitride crystal is grown from the seed crystal with the c-plane as the principal face by the flux method using the conventional producing method, more cracks occur in a {10-11} growth area 32B of the obtained group 13 nitride single crystal 41 than in a c-plane growth area 32A. The inventors of the present invention have found out that the cracks occurring in the {10-11} growth area 32B propagate toward the c-plane growth area 32A from the {10-11} growth area 32B.

In addition, the inventors of the present invention have found out that, in the conventional producing method, the {10-11} growth area 32B is higher in an oxygen content than the c-plane growth area 32A of the obtained group 13 nitride single crystal 41. The inventors of the present invention have also found out that the high oxygen content causes the cracks.

Consequently, the inventors of the present invention have found out that cracks can be reduced by inhibiting the {10-11} growth of the group 13 nitride crystal originating from the seed crystal 30.

Consequently, it is considered that the {10-11} growth of a group 13 nitride crystal 32 that grows from the seed crystal 30 is inhibited by arranging a surrounding member so as to cover the entire area of the side face of the seed crystal 30 with the c-plane as the principal face. For this reason, it is considered that cracks can be reduced.

The following describes the details.

### First Embodiment

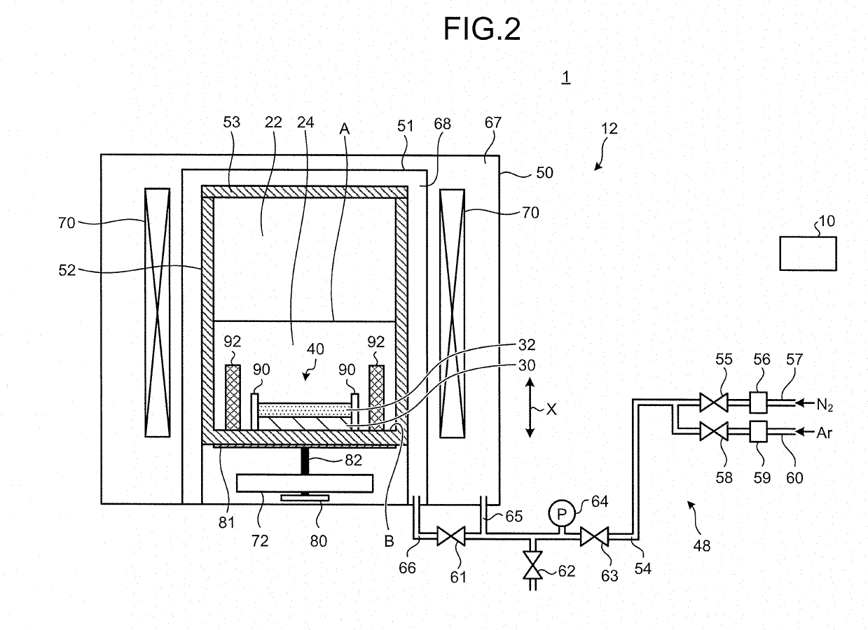

FIG. 2 is a diagram of an example of an apparatus 1 for producing a group 13 nitride single crystal for implementing a method for producing a group 13 nitride single crystal in the present embodiment. In the following, the “apparatus for producing a group 13 nitride single crystal” may be described simply referred to as a producing apparatus.

The producing apparatus 1 includes a controller 10 and a main body 12. The controller 10 controls the main body 12.

The main body 12 includes an external pressure-resistant vessel 50. The external pressure-resistant vessel 50 is made of stainless steel, for example. An internal vessel 51 is placed within the external pressure-resistant vessel 50. The internal vessel 51 has a closed shape. The internal vessel 51 is made of stainless steel, for example. The internal vessel 51 is removable from the external pressure-resistant vessel 50.

A reaction vessel 52 is arranged within the internal vessel 51. In other words, the reaction vessel 52 is arranged inside a double structure vessel of the external pressure-resistant vessel 50 and the internal vessel 51. The internal vessel 51 is detachable from and attachable to the external pressure-resistant vessel 50. The reaction vessel 52 contains a mixed melt 24.

An external bottom of the reaction vessel 52 is supported by a turn table 81. The turn table 81 is a plate-shaped member having a plate face along a horizontal face. The turn table 81 is supported by a supporting member 82. The supporting member 82 supports the center of the plate face of the turn table 81. The supporting member 82 is a member elongating in a vertical direction; one end in a longitudinal direction is connected to the center of the plate face of the turn table 81, whereas the other end is connected to a drive unit 80. The drive unit 80 is a drive unit that rotatingly drives the turn table 81 with the supporting member 82 as a rotary shaft.

The drive unit 80 is electrically connected to the controller 10. The drive unit 80 rotates the turn table 81 with the supporting member 82 as the rotary shaft under control of the controller 10. The rotation of the turn table 81 rotates the reaction vessel 52. The rotation (rotational speed, rotational direction, and the like) of this reaction vessel 52 is controlled, whereby the mixed melt 24 contained in the reaction vessel 52 is stirred.

A mechanism that stirs the mixed melt 24 within the reaction vessel 52 is not limited to the mechanism implemented by the turn table 81, the supporting member 82, and the drive unit 80. The mechanism that stirs the mixed melt 24 within the reaction vessel 52 may shake the reaction vessel 52, for example. The turn table 81 may rotatably support the reaction vessel 52 and a first heating unit 70.

The reaction vessel 52 contains the seed crystal 30 and a surrounding member 90 in the mixed melt 24, which the reaction vessel 52 contains. In other words, the reaction vessel 52 is a vessel for containing the seed crystal 30 and the mixed melt 24 to grow the group 13 nitride crystal 32 from the seed crystal 30. In the example illustrated in FIG. 2, the reaction vessel 52 is provided with a lid 53, which functions as a lid that closes an opening of the reaction vessel 52.

The material of the reaction vessel 52 is not limited to a particular material. Examples of the material of the reaction vessel 52 include nitrides such as BN sintered bodies, boron nitride, and aluminum nitride, oxides such as alumina (Al₂O₃) and YAG, and carbides such as SiC. An inner wall face of the reaction vessel 52, that is, a part by which the reaction vessel 52 is in contact with the mixed melt 24 is preferably formed of a material that is difficult to react with (or be dissolved in) the mixed melt 24. When the group 13 nitride crystal 32 is a gallium nitride crystal, examples of the material of the reaction vessel 52 include nitrides such as boron nitride (BN), pyrolytic BN (P-BN), and aluminum nitride, oxides such as alumina, yttrium aluminum garnet (YAG), and stainless steels (SUS).

The mixed melt 24 contained in the reaction vessel 52 contains at least an alkali metal as a flux and a group 13 metal.

Examples of the flux include metallic sodium and sodium compounds (sodium azide, for example). In the present embodiment, described as an example is a case in which sodium (Na) as an alkali metal is used as the flux.

The purity of the sodium contained in the mixed melt 24 is preferably 99.95% or higher. When the purity of the sodium contained in the mixed melt 24 is 99.95% or higher, crude crystals are inhibited from occurring on the surface of the mixed melt 24. In addition, when the purity of the sodium contained in the mixed melt 24 is 99.95% or higher, a reduction in the crystal growth rate of the group 13 nitride crystal 32 that grows on the seed crystal 30 can be inhibited.

In the present embodiment, described is a case in which at least gallium is used as the group 13 metal contained in the mixed melt 24. Consequently, in the present embodiment, the mixed melt 24 is described as a melt with sodium (Na) and gallium (Ga) as main components.

Other group 13 metals such as boron, aluminum, and indium may be used as the group 13 metal, and a mixture of a plurality of metals selected from group 13 metals may be used.

A group 13 nitride single crystal 40 produced in the present embodiment may mean gallium nitride, aluminum nitride, indium nitride, and mixed crystals thereof.

The molar ratio between the group 13 metal and the alkali metal contained in the mixed melt 24 is not limited to a particular ratio; the ratio of the molar number of the alkali metal to the total molar number of the group 13 metal and the alkali metal is preferably 40 mol % to 95 mol %.

To the mixed melt 24, additives having an effect of enlarging a metastable area in which nucleation is inhibited or boron oxide or gallium oxide as an n-type dopant raw material may be added as appropriate.

Examples of the additives include carbon (C) that forms CN ions in the flux to play a role of increasing a nitrogen concentration within the mixed melt 24 and alkali metals such as Li and K and alkaline earth metals such as Mg, Ca, and Sr that play a role of changing a nitrogen take-in amount and nitrogen solubility within the mixed melt 24. Examples of the n-type dopant include germanium (Ge).

The amount of carbon to be added as an additive to the mixed melt 24 is not limited to a particular amount. The amount of carbon to be added as the additive to the mixed melt 24 is desirably in a range of from 0.1 at % to 5 at % inclusive relative to the total molar number of the group 13 element and the alkali metal contained in the mixed melt 24, for example. The amount of carbon is preferably 0.4 at % or more and 2.0 at % or less and further preferably 0.5 at % or more and 1.2 at % or less.

The amount of germanium to be added as an n-type dopant to the mixed melt 24 is not limited to a particular amount. The amount of germanium to be added is preferably 0.1 at % or more and 5 at % or less, further preferably 0.5 at % or more and 3.0 at % or less, and particularly preferably 1.5 at % or more and 2.5 at % or less relative to the molar number of the group 13 element contained in the mixed melt 24, for example.

The seed crystal 30 arranged within the mixed melt 24 of the reaction vessel 52 is a group 13 nitride crystal with the c-plane as the principal face.

For the seed crystal 30, preferably used is a self-supporting GaN substrate to which a heterogeneous substrate such as sapphire is not attached.

A method for producing the seed crystal 30 is not limited to a particular method. The seed crystal 30 is produced by a vapor phase growth method or a liquid phase growth method, for example. The vapor phase growth method is a hydride vapor phase epitaxy (HVPE) method, for example. The liquid phase growth method is a flux method or an ammonothermal method, for example.

When the HVPE method is used, the seed crystal 30 may be produced by growing a group 13 nitride crystal on the c-plane of a sapphire substrate using the HVPE method and adjusting crystal growth conditions, for example.

The shape of the seed crystal 30 is not limited; the c-plane as the principal face is preferably a flat face, and the c-plane is further preferably a mirror face.

An off angle (an angle of inclination) of the principal face of the seed crystal 30 relative to a <0001> direction is preferably 2 degrees or smaller. When the off angle of the principal face of the seed crystal 30 relative to the <0001> direction is 2 degrees or smaller, the amount of inclusions contained in the group 13 nitride crystal 32 that grows can be reduced. The off angle of the principal face of the seed crystal 30 relative to the <0001> direction is further preferably 0.5 degree or smaller.

The seed crystal 30 is arranged on an inside bottom B of the reaction vessel 52. Specifically, the seed crystal 30 is arranged within the reaction vessel 52 such that the principal face of the seed crystal 30 is directed toward a vapor-liquid interface A between the mixed melt 24 and a vapor phase 22 and that a bottom face as the opposite face of the principle face of the seed crystal 30 is in contact with the inside bottom B of the reaction vessel 52.

In the present embodiment, the surrounding member 90 is arranged within the reaction vessel 52. The surrounding member 90 is arranged so as to surround the entire area of the side face of the seed crystal 30.

As described above, the side face of the seed crystal 30 is a face of the outer wall faces forming the seed crystal 30 that is continuous to the principal face (the c-plane) of the seed crystal 30 and crosses the principal face. In other words, the side face of the seed crystal 30 is a face of the outer wall faces forming the seed crystal 30 other than the c-plane as the principal face and the bottom face opposite to (substantially parallel to) the principal face.

The arrangement surrounding the entire area of the side face of the seed crystal 30 means that the side face of the seed crystal 30 is surrounded across the 360-degree circumference about the normal line of the principal face of the seed crystal 30 and that the side face is surrounded from one end to the other end in a first direction (refer to the arrow X direction in the drawings, which may be hereinafter referred to as a first direction X) that is orthogonal to the principal face.

As illustrated in FIG. 2, the surrounding member 90 is arranged on the inside bottom B of the reaction vessel 52. Specifically, the surrounding member 90 is arranged such that one end face in the first direction X is in contact with the bottom B, whereas the other end face is directed toward the vapor-liquid interface A.

In the present specification, the first direction X is a direction coinciding with the normal line direction of the principal face (the c-plane) of the seed crystal 30 when the seed crystal 30 and the surrounding member 90 are arranged on the inside bottom B of the reaction vessel 52. Consequently, the first direction X of the surrounding member 90 indicates the direction coinciding with the normal line direction of the c-plane of the seed crystal 30 when the surrounding member 90 is arranged on the bottom B of the reaction vessel 52 so as to surround a side face Q of the seed crystal 30 by an inner wall P of the surrounding member 90.

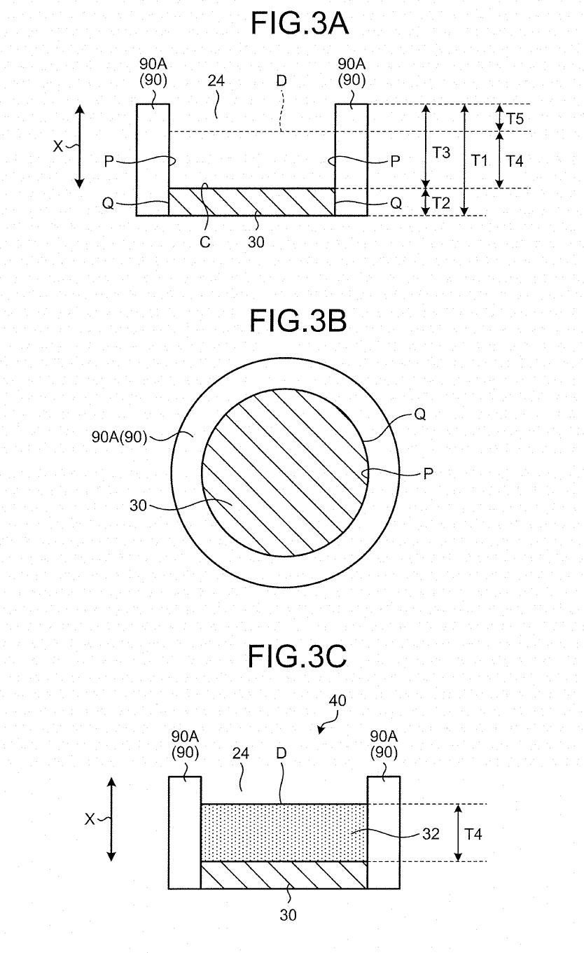

FIG. 3A to FIG. 3C are illustrative diagrams of an example of the surrounding member 90 (a surrounding member 90A). FIG. 3A is a sectional view of the seed crystal 30 and the surrounding member 90. FIG. 3B is a top view of the seed crystal 30 and the surrounding member 90. FIG. 3C is a sectional view illustrating a state in which the group 13 nitride crystal 32 has grown on the seed crystal 30.

The surrounding member 90A has a shape along the outer circumference of the side face of the seed crystal 30, for example. Specifically, in the surrounding member 90A, the shape of the inner wall P at a section orthogonal to the first direction X is similar to a sectional shape orthogonal to the first direction X of the seed crystal 30 (the shape of a principal face C, for example). The example illustrated in FIG. 3A to FIG. 3C illustrates a case in which the shape of the principal face C of the seed crystal 30 is circular, and the surrounding member 90A is a cylindrical member as an example. In other words, FIG. 3A to FIG. 3C illustrate a case in which the shape of the inner wall P at the section orthogonal to the first direction X of the surrounding member 90A is circular (perfectly circular).

The distance of a gap between the side face Q of the seed crystal 30 and the surrounding member 90 is not limited. The distance of the gap between the side face Q of the seed crystal 30 and the surrounding member 90 indicates the shortest distance of the gap (clearance) in a direction orthogonal to the first direction X between the side face Q of the seed crystal 30 and the inner wall P of the surrounding member 90.

The distance of the gap between the side face Q of the seed crystal 30 and the surrounding member 90 is preferably shorter than 5 mm, further preferably shorter than 2 mm, and particularly preferably 0 mm.

The state in which the distance of the gap between the side face Q of the seed crystal 30 and the surrounding member 90 is 0 mm is a state in which the side face Q of the seed crystal 30 and the inner wall P of the surrounding member 90 are arranged in contact with each other. FIG. 3A to FIG. 3C illustrate a mode in which the inner wall P of the surrounding member 90A and the side face Q of the seed crystal 30 are arranged in contact with each other.

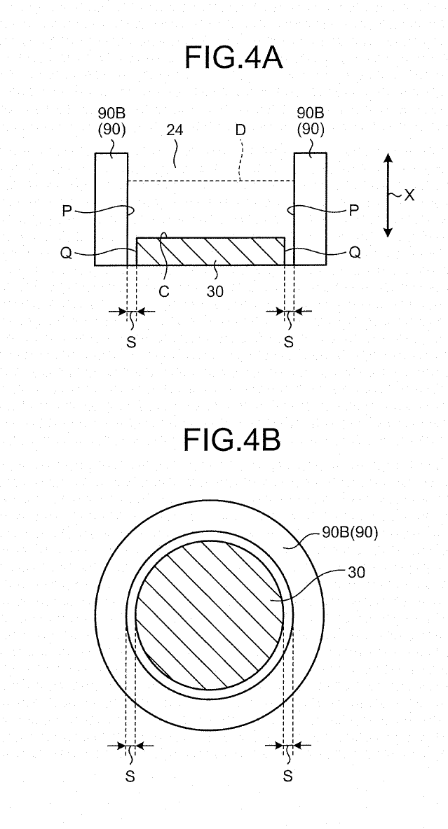

FIG. 4A and FIG. 4B are illustrative diagrams of an example of a mode in which the gap between the inner wall P of the surrounding member 90 (a surrounding member 90B) and the side face Q of the seed crystal 30 exceeds 0 mm. FIG. 4A is a sectional view of the seed crystal 30 and the surrounding member 90B. FIG. 4B is a top view of the seed crystal 30 and the surrounding member 90B.

As illustrated in FIGS. 4A and 4B, the distance of a gap S between the side face Q of the seed crystal 30 and the surrounding member 90 may be a value exceeding 0 mm. However, as described above, the distance of the gap between the side face Q of the seed crystal 30 and the surrounding member 90 is preferably a distance within the range, and particularly preferably, the side face Q of the seed crystal 30 and the inner wall P of the surrounding member 90 are arranged in contact with each other as illustrated in FIG. 3A to FIG. 3C.

The gap between the side face Q of the seed crystal 30 and the inner wall P of the surrounding member 90 is made within the range, whereby the occurrence of cracks in the group 13 nitride single crystal 40 to be produced can be further reduced. This is because it is considered that when the gap between the side face Q of the seed crystal 30 and the inner wall P of the surrounding member 90 is within the range, the formation of a {10-11} plane can be effectively inhibited in the group 13 nitride crystal 32 that grows from the seed crystal 30.

The gap between the side face Q of the seed crystal 30 and the inner wall P of the surrounding member 90 is preferably constant (the same distance) across the 360-degree circumference about the normal line of the principal face C of the seed crystal 30.

Referring back to FIG. 3A to FIG. 3C, the length in the first direction X of the surrounding member 90 (hereinafter, referred to as a first length, and refer to a first length T1 in FIG. 3A to FIG. 3C) is not limited. However, the first length T1 in the first length X of the surrounding member 90 is preferably longer than the length in the first direction X of the seed crystal 30 (hereinafter, referred to as a second length, and refer to a second length T2 in FIG. 3A to FIG. 3C). The surrounding member 90 is preferably arranged such that one end in the first direction X of the surrounding member 90 protrudes toward the vapor-liquid interface A from the principal face C of the seed crystal 30 (refer to also FIG. 2).

In other words, the seed crystal 30 is arranged such that the opposite face of the principal face C of the seed crystal 30 is in contact with the inside bottom B of the reaction vessel 52, whereas the surrounding member 90 in which the first length T1 is longer than the second length T2 is arranged so as to surround the side face Q of the seed crystal 30 and such that one end face in the first direction X is in contact with the bottom B. With this arrangement, one end in the first direction X of the surrounding member 90 protrudes from the principal face C of the seed crystal 30.

The length in the first direction X of an area of the surrounding member 90 protruding from the principal face C of the seed crystal 30 (hereinafter, referred to as a third length, and refer to a third length T3 in FIG. 3A to FIG. 3C) is preferably longer than a target thickness T4 set in advance of the group 13 nitride crystal 32 grown on the principal face C of the seed crystal 30.

The target thickness T4 is a length in the first direction X of the group 13 nitride crystal 32 grown on the seed crystal 30 (refer to FIG. 3A and FIG. 3C). In other words, the target thickness T4 is a length (the shortest distance) in the first direction X from the principal face C of the seed crystal 30 to a position D at a target thickness of the group 13 nitride crystal 32 grown on the seed crystal 30.

Consequently, the first length T1 in the first direction X of the surrounding member 90 may be adjusted in advance in accordance with the target thickness T4 of the group 13 nitride single crystal 40 to be produced (that is, the group 13 nitride crystal 32 that grows).

It is considered that when the third length T3 of the area of the surrounding member 90 protruding from the principal face C of the seed crystal 30 is longer than the target thickness T4 set in advance of the group 13 nitride crystal 32 grown on the principal face C of the seed crystal 30, the {10-11} growth of the group 13 nitride crystal 32 can be effectively inhibited, and the occurrence of cracks can be further reduced.

It is considered that this is because the group 13 nitride crystal 32 that grows on the seed crystal 30 is inhibited from growing up to a position beyond the end of the surrounding member 90 directed toward the vapor-liquid interface A, whereby the {10-11} plane can be inhibited from being formed in a part beyond the end.

A subtracted value obtained by subtracting the target thickness T4 of the group 13 nitride crystal 32 grown from the third length T3 in the first direction X of the area of the surrounding member 90 protruding from the principal face C of the seed crystal 30 (refer to a subtracted value T5 in FIG. 3A to FIG. 3C) is preferably 0 mm or more and 10 mm or less, further preferably 0 mm or more and 5 mm or less, and particularly preferably 0 mm or more and 1 mm or less.

When the subtracted value T5 is within the range, at least one of stagnation of the flow of the mixed melt 24 contained in the reaction vessel 52, abnormal growth of the group 13 nitride crystal 32, polycrystallization of the group 13 nitride crystal 32, and an increase in the take-in amount of inclusions near the outer circumference of the group 13 nitride crystal 32 can be inhibited.

The component of the surrounding member 90 is not limited. Examples of the component of the surrounding member 90 include oxides such as aluminum oxide (Al₂O₃) and aluminum titanate (Al₂TiO₅), nitrides such as silicon nitride (Si₃N₄) and aluminum nitride (AlN), carbides such as silicon carbide (SiC), mixed materials formed of combinations of oxides, nitrides, and carbides, high melting point metals such as tungsten (W), and alloys such as invar.

The surrounding member 90 and the group 13 nitride crystal 32 grown on the seed crystal 30 preferably have different main components. It is considered that a material that differs in the main component from the group 13 nitride crystal 32 is used as the surrounding member 90, whereby the occurrence of cracks can be further reduced. It is considered that this is because the group 13 nitride crystal 32 that grows and the surrounding member 90 become an integral crystal, whereby the occurrence of cracks caused by the formation of the {10-11} growth area on the side face of the crystal can be inhibited.

In view of differentiating the surrounding member 90 and the group 13 nitride crystal 32 in the main component, when the group 13 nitride crystal 32 is GaN, for example, the surrounding member 90 preferably has aluminum oxide (Al₂O₃), aluminum titanate (Al₂TiO₅), silicon nitride (Si₃N₄), aluminum nitride (AlN), silicon carbide (SiC), tungsten (W), invar, or the like as the main component.

The component of the surrounding member 90 is preferably smaller in the coefficient of thermal expansion than the group 13 nitride crystal 32 grown on the seed crystal 30. In the crystal growth process, the side face of the group 13 nitride crystal 32 grows up to the inner wall P of the surrounding member 90. For this reason, it is considered that a material that is smaller in the coefficient of thermal expansion than the group 13 nitride crystal 32 grown on the seed crystal 30 is used as the component of the surrounding member 90, whereby the occurrence of cracks caused by strain or the like caused by the difference in the coefficient of thermal expansion between the group 13 nitride crystal 32 that has grown and the surrounding member 90 when the temperature has decreased after the end of crystal growth can be reduced.

In terms of the coefficient of thermal expansion, when the group 13 nitride crystal 32 is GaN, for example, preferably used for the surrounding member 90 is aluminum titanate (Al₂TiO₅), silicon nitride (Si₃N₄), aluminum nitride (AlN), tungsten (W), invar, or the like, which are smaller in the coefficient of thermal expansion than GaN.

Preferably used for the component of the surrounding member 90 is a material that is difficult to nucleate and is high in corrosion resistance against the mixed melt 24. When the material that is difficult to nucleate and is high in corrosion resistance against the mixed melt 24 is used for the component of the surrounding member 90, the occurrence of cracks caused by the formation of the {10-11} growth area can be further reduced.

It is considered that the surrounding member 90 is formed of the material that is difficult to nucleate, whereby a crystal that has nucleated on the surrounding member 90 and the group 13 nitride crystal 32 that has grown from the seed crystal 30 become an integral crystal, and the {10-11} plane can be inhibited from being formed from the side face of the integral crystal. In addition, it is considered that the material that is high in corrosion resistance against the mixed melt 24 is used for the surrounding member 90, whereby the surrounding member 90 is inhibited from being dissolved in the mixed melt 24 or becoming deformed, and the {10-11} plane can be inhibited from being formed on the group 13 nitride crystal 32 that grows.

In terms of nucleation and corrosion resistance, preferably used for the component of the surrounding member 90 is a material that is a mixed material of an oxide and a nitride containing the nitride material as a main component (the content of which is 80% by mass or higher) and containing the oxide material in an amount of 0.1% by mass or higher and 20% by mass or lower, for example.

As to a material that satisfies all the requirements including being different in the main component from the group 13 nitride crystal 32, being smaller in the coefficient of thermal expansion than the group 13 nitride crystal 32, being difficult to nucleate, and being high in corrosion resistance against the mixed melt 24, particularly preferably used for the surrounding member 90 is a material that contains aluminum nitride (AlN) as a main component and contains yttrium oxide (Y₂O₃) in an amount of 5% by mass or higher and 7% by mass or lower among the components described above.

Referring back to FIG. 2, in the present embodiment, plate-shaped members 92 are preferably placed within the reaction vessel 52. The plate-shaped members 92 are plate-shaped members elongate in the first direction X and are arranged such that one end side in the longitudinal direction is in contact with the bottom face of the reaction vessel 52 and that the other end side faces the vapor-liquid interface A. The plate-shaped members 92 are arranged between the surrounding member 90 and the inner wall of the reaction vessel 52 on the bottom B of the reaction vessel 52.

The plate-shaped members 92 function as baffles (baffle boards) that cause the stirring of the mixed melt 24 within the reaction vessel 52 to further proceed when the turn table 81 rotates or stops the rotation of the reaction vessel 52. The plate-shaped members 92 are arranged within the reaction vessel 52, whereby the mixed melt 24 is efficiently stirred along with the rotation of the reaction vessel 52. When the mixed melt 24 is not stirred, the plate-shaped members 92 are not necessarily placed within the reaction vessel 52.

The producing apparatus 1 is provided with a supply unit 48. The supply unit 48 supplies nitrogen to the vapor phase 22 within the reaction vessel 52 and dissolves nitrogen in the mixed melt 24.

The supply unit 48 includes a gas supply pipe 65, a gas supply pipe 66, a nitrogen supply pipe 57, a pressure control apparatus 56, a valve 55, a gas supply pipe 54, a gas supply pipe 60, a pressure control apparatus 59, a valve 58, a valve 63, a valve 61, and a valve 62.

The gas supply pipe 65 and the gas supply pipe 66 are connected to the external pressure-resistant vessel 50 and the internal vessel 51. The gas supply pipe 65 and the gas supply pipe 66 supply a nitrogen (N₂) gas as a raw material of the group 13 nitride single crystal 40 and a diluent gas for total pressure adjustment to an internal space 67 of the external pressure-resistant vessel 50 and an internal space 68 of the internal vessel 51, respectively.

The nitrogen gas and the diluent gas are supplied to the vapor phase 22 within the reaction vessel 52.

Although an argon (Ar) gas as an inert gas is desirably used as the diluent gas, this is not limiting; other inert gases such as helium (He) and neon (Ne) may be used as the diluent gas.

The nitrogen gas is supplied from the nitrogen supply pipe 57 connected to a gas cylinder or the like of the nitrogen gas, is subjected to pressures adjustment by the pressure control apparatus 56, and is then supplied to the gas supply pipe 54 via the valve 55. The gas for total pressure adjustment (the argon gas, for example) is supplied from the gas supply pipe 60 for total pressure adjustment connected to a gas cylinder or the like of the gas for total pressure adjustment, is subjected to pressure adjustment by the pressure control apparatus 59, and is then supplied to the gas supply pipe 54 via the valve 58. The nitrogen gas and the gas for total pressure adjustment thus subjected to pressure adjustment are supplied to the gas supply pipe 54 to be mixed with each other.

A mixed gas of nitrogen and the diluent gas is supplied to the inside of the external pressure-resistant vessel 50 and the internal vessel 51 from the gas supply pipe 54 via the valve 63, the gas supply pipe 65, the valve 61, and the gas supply pipe 66. The internal vessel 51 is detachable from the producing apparatus 1 at the part of the valve 61. The gas supply pipe 65 communicates with the outside via the valve 62.

The gas supply pipe 54 is provided with a pressure gauge 64. In the producing apparatus 1, the controller 10 adjusts the pressure within the external pressure-resistant vessel 50 and the internal vessel 51 while monitoring the total pressure within the external pressure-resistant vessel 50 and the internal vessel 51 by the pressure gauge 64.

In the present embodiment, the producing apparatus 1 thus adjusts the pressures of the nitrogen gas and the diluent gas by the valve 55 and valve 58, respectively, and the pressure control apparatus 56 and the pressure control apparatus 59, respectively, and can thereby adjust a nitrogen partial pressure. Because the total pressure of the external pressure-resistant vessel 50 and the internal vessel 51 is adjustable, the total pressure within the internal vessel 51 can be increased, whereby the evaporation of the flux (sodium, for example) within the reaction vessel 52 can be inhibited. In other words, the nitrogen partial pressure as a nitrogen raw material that has an effect on the crystal growth conditions of gallium nitride and the total pressure that has an effect on the inhibition of evaporation of the flux such as sodium can be controlled separately.

The nitrogen partial pressure within the internal vessel 51 during the crystal growth of the group 13 nitride crystal 32 is determined by the size or the like of the group 13 nitride crystal 32 to be produced, and the value thereof is not limited. The nitrogen partial pressure within the internal vessel 51 is preferably within the range of from 0.1 MPa to 8 MPa, for example.

The first heating unit 70 and a second heating unit 72 are arranged around the outer circumference of the internal vessel 51 within the external pressure-resistant vessel 50. In the present embodiment, the first heating unit 70 is arranged along the side face of the internal vessel 51. The second heating unit 72 is arranged on the bottom face side outside the reaction vessel 52.

The first heating unit 70 and the second heating unit 72 heat the internal vessel 51 and the reaction vessel 52 to heat the mixed melt 24 within the reaction vessel 52. Heating temperatures by the first heating unit 70 and the second heating unit 72 are adjusted, whereby desired temperature distribution can be formed within the mixed melt 24.

Production of Group 13 Nitride Crystal

In the producing method according to the present embodiment, the group 13 nitride single crystal 40 is produced using the producing apparatus 1.

Dissolution Process

In the dissolution process, nitrogen is dissolved in the mixed melt 24 in the reaction vessel 52 that contains the mixed melt 24 and the seed crystal 30 with the c-plane as the principal face C and the surrounding member 90 arranged so as to surround the entire area of the side face Q that is continuous to the principal face C of the seed crystal 30 and crosses the principal face C that are placed within the mixed melt 24.

Specifically, first, the seed crystal 30 and the surrounding member 90 are arranged within the reaction vessel 52. The placing positions of the seed crystal 30 and the surrounding member 90 and the details of the seed crystal 30 and the surrounding member 90 are as described above. Within the reaction vessel 52, the plate-shaped members 92 may be further arranged.

The raw materials of the mixed melt 24 and the like are then charged into this reaction vessel 52. Work for charging the raw materials into the reaction vessel 52 is performed with the internal vessel 51 put into a glove box with an atmosphere of an inert gas such as an argon gas, for example. This work may be performed with the reaction vessel 52 put into the internal vessel 51. The glove box is controlled in an oxygen value and a dew point; the raw materials are charged with an oxygen value of 0.10 ppm or less and a dew point of −100° C. or lower. There is no special limitation on the order of charging the raw materials.

The reaction vessel 52 that arranges therewithin the mixed melt 24, the seed crystal 30, and the surrounding member 90 is arranged in the producing apparatus 1. Furthermore, the first heating unit 70 and the second heating unit 72 are energized to heat the internal vessel 51 and the reaction vessel 52 therewithin to a crystal growth temperature. With this heating, the inside of the reaction vessel 52 is heated to the crystal growth temperature. The crystal growth temperature is 750° C. or higher, for example. The nitrogen partial pressure within the internal vessel 51 is preferably within the range of from 0.1 MPa to 8 MPa, for example.

The group 13 metal, the alkali metal, and other additives as the raw materials then melt within the reaction vessel 52 to form the mixed melt 24. The nitrogen with the above partial pressure is supplied from the vapor phase 22 to this mixed melt 24 to dissolve the nitrogen in the mixed melt 24.

Crystal Growth Process

In the crystal growth process, the group 13 nitride crystal 32 is grown on the seed crystal 30.

Specifically, the first heating unit 70 and the second heating unit 72 are energized to heat the mixed melt 24 to the crystal growth temperature, and the state in which the nitrogen partial pressure is maintained is continued for a crystal growth time set in advance. With this process, the group 13 nitride crystal 32 grows from the principal face C of the seed crystal 30. The group 13 nitride crystal 32 grows from the principal face C of the seed crystal 30, whereby the group 13 nitride single crystal 40 is produced.

The crystal growth time in the crystal growth process is determined based on a target size or thickness of the group 13 nitride single crystal 40 to be produced. The crystal growth time is about a few tens of hours to one thousand hours, for example.

The crystal growth process is preferably carried out while stirring the mixed melt 24.

The stirring of the mixed melt 24 may be performed by controlling the drive unit 80 by the controller 10. The mixed melt 24 within the reaction vessel 52 may be stirred by causing the controller 10 to control the drive unit 80, thereby rotating the reaction vessel 52 via the turn table 81.

When the mixed melt 24 is rigorously stirred, crude crystals may occur. For this reason, the stirring rate of the mixed melt 24 is preferably a rate that can inhibit the occurrence of crude crystals.

The stirring rate of the mixed melt 24 may be constant or variable. However, the stirring rate is preferably made variable. In other words, the controller 10 preferably stirs the mixed melt 24 by rotation control including the acceleration, deceleration, and inversion of the reaction vessel 52 so as to maintain a state in which a difference has occurred between the rotational speed of the seed crystal 30 and of the group 13 nitride crystal 32 that has grown from the seed crystal 30 and the rotational speed of the mixed melt 24. The stirring of the mixed melt 24 is preferably being performed at a time when the mixed melt 24 has been formed within the reaction vessel 52.

It is considered that by stirring the mixed melt 24 in the crystal growth process, nitrogen concentration distribution within the mixed melt 24 is inhibited from becoming nonuniform, and that the group 13 nitride single crystal 40 with high quality and large size can be produced.

The crystal growth conditions (parameters such as the crystal growth temperature, the nitrogen partial pressure, the rotational speed of the mixed melt 24, the rotational acceleration of the mixed melt 24, the rotational deceleration of the mixed melt 24, the rotation time of the mixed melt 24, and the rotation downtime of the mixed melt 24) in the crystal growth process can be freely adjusted and changed by setting changes by a user and control by the controller 10.

Through the crystal growth process, the group 13 nitride crystal 32 grows up to the position D at the target thickness on the seed crystal 30, whereby the group 13 nitride single crystal 40 is produced as illustrated in FIG. 3C.

In this process, the surrounding member 90 inhibits the {10-11} growth of the group 13 nitride crystal 32, and c-plane growth mainly occurs as described above. Consequently, it is considered that the present embodiment can reduce cracks in the group 13 nitride single crystal 40.

Post-Process

A post-process is preferably carried out after the crystal growth process.

First, when the crystal growth in the crystal growth process ends, the reaction vessel 52 is allowed to stand until the temperature of the mixed melt 24 decreases to about room temperature.

The temperature decreasing rate of the mixed melt 24 after the crystal growth process is preferably a rate that is the same as or slower than the temperature rising rate to the crystal growth temperature at the starting of crystal growth.

Such a temperature decreasing rate can further reduce the occurrence of cracks caused by a difference in the coefficient of thermal expansion between the seed crystal 30 and the group 13 nitride crystal 32 that has grown.

After the temperature of the mixed melt 24 has decreased to about room temperature, the reaction vessel 52 is taken out of the external pressure-resistant vessel 50 together with the internal vessel 51. Residual substances such as sodium, gallium, and a gallium-sodium alloy remain within the reaction vessel 52 apart from the produced group 13 nitride single crystal 40.

Given this situation, sodium is preferably removed by immersing the reaction vessel 52 into alcohol such as ethanol, or sodium is preferably removed by melting the sodium within a glove box under an inert gas atmosphere, washing the sodium out of the reaction vessel 52, and immersing the reaction vessel 52 into alcohol such as ethanol. In terms of working efficiency, the sodium is preferably washed out by melting.

In the reaction vessel 52 after the sodium has been removed, the gallium and the gallium-sodium alloy remain apart from the produced group 13 nitride single crystal 40. The gallium-sodium alloy is reacted with water at a temperature of 50° C. or higher to dissolve only a sodium component, thereby collecting the gallium, or the sodium component is dissolved with acid such as nitric acid, hydrochloric acid, or aqua regia, thereby collecting the gallium. After the gallium-sodium alloy has been removed, the group 13 nitride single crystal 40 is taken out and is washed with acid such as aqua regia.

Through the process, the group 13 nitride single crystal 40 is obtained.

As described above, the method for producing the group 13 nitride single crystal 40 according to the present embodiment includes the dissolution process and the crystal growth process. The dissolution process is a process that dissolves nitrogen in the mixed melt 24 in the reaction vessel 52 that contains the mixed melt 24, the seed crystal 30, and the surrounding member 90.

The mixed melt 24 contains the alkali metal and the group 13 metal. The seed crystal 30 is a seed crystal that is placed within the mixed melt 24 and is formed of the group 13 nitride crystal in which the principal face is the c-plane. The surrounding member 90 is arranged so as to surround the entire area of the side face of the seed crystal 30. The crystal growth process grows the group 13 nitride crystal 32 on the seed crystal 30.

Consequently, it is considered that the method for producing the group 13 nitride single crystal 40 according to the present embodiment can reduce cracks in the group 13 nitride single crystal 40.

A distance S of the gap between the side face Q of the seed crystal 30 and the surrounding member 90 is preferably shorter than 5 mm, preferably shorter than 2 mm, and particularly preferably 0 mm (contact arrangement).

The first length T1 in the first direction X orthogonal to the principal face C of the surrounding member 90 is preferably longer than the second length T2 in the first direction X of the seed crystal 30. The surrounding member 90 is preferably arranged such that the one end in the first direction X of the surrounding member 90 protrudes toward the vapor-liquid interface A from the principal face C of the seed crystal 30.

The third length T3 in the first direction X of the area protruding toward the vapor-liquid interface A from the principal face C of the surrounding member 90 is preferably longer than the target thickness T4 set in advance of the group 13 nitride crystal 32 grown on the principal face C.

The surrounding member 90 and the group 13 nitride crystal 32 grown on the seed crystal 30 preferably have different main components. The surrounding member 90 is preferably smaller in the coefficient of thermal expansion than the group 13 nitride crystal 32 grown on the seed crystal 30.

The reaction vessel 52 may contain an oxide material.

The producing apparatus 1 according to the present embodiment is an apparatus configured to produce a group 13 nitride single crystal 40 by a flux method. The producing apparatus 1 includes the reaction vessel 52. The reaction vessel 52 contains the mixed melt 24, the seed crystal 30, and the surrounding member 90.

### Second Embodiment

The first embodiment shows a case in which the shape of the inner wall P at a section orthogonal to the first direction X of the surrounding member 90 is perfectly circular as an example (refer to the surrounding member 90A in FIG. 3A to FIG. 3C and the surrounding member 90B in FIG. 4A and FIG. 4B).

However, the shape of the inner wall P of the surrounding member 90 is not limited to be perfectly circular.

The shape of the inner wall P of the surrounding member 90 may be a shape corresponding to the shape of the group 13 nitride single crystal 40 to be formed, for example.

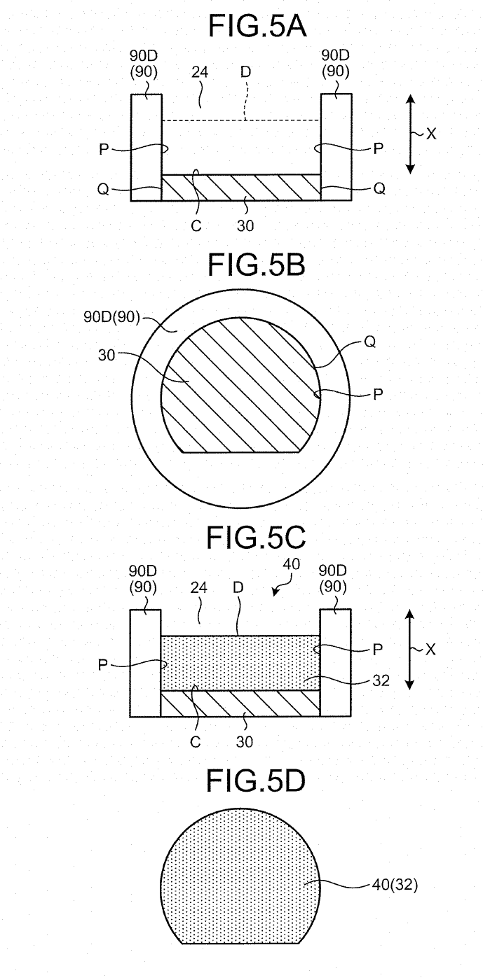

FIG. 5A to FIG. 5D are illustrative diagrams of an example of the surrounding member 90 according to the present embodiment (a surrounding member 90D). FIG. 5A is a sectional view of the seed crystal 30 and the surrounding member 90D. FIG. 5B is a top view of the seed crystal 30 and the surrounding member 90D. FIG. 5C is a sectional view illustrating a state in which the group 13 nitride crystal 32 has grown on the seed crystal 30. FIG. 5D is a top view of an example of the group 13 nitride single crystal 40 that has been produced.

It is assumed that the shape of the group 13 nitride single crystal 40 to be formed is a shape having orientation flat (OF) as illustrated in FIG. 5D, for example. In other words, it is assumed that the shape of the c-plane of the group 13 nitride single crystal 40 to be formed has a shape having the orientation flat, in which part of the outer circumference shown by a perfect circle is designed as a line (an orientation flat part).

In this case, the sectional shape in a direction orthogonal to the first direction X of the inner wall P of the surrounding member 90D may be a shape along the outer shape of the group 13 nitride single crystal 40 to be formed having the orientation flat as illustrated in FIG. 5B.

Using the surrounding member 90D having the inner wall P of the shape along the shape of the group 13 nitride single crystal 40 to be formed, the dissolution process and the crystal growth process are carried out similarly to the first embodiment. With this procedure, the group 13 nitride crystal 32 grows along the inner wall P of the surrounding member 90D from the principal face C of the seed crystal 30 as illustrated in FIG. 5C. Consequently, the group 13 nitride single crystal 40 to be formed of any shape can be easily produced as illustrated in FIG. 5D.

Consequently, it is considered that the present embodiment can produce the group 13 nitride single crystal 40 of a target shape further easily in addition to the effect of the first embodiment. In addition, the present embodiment can also simplify a process of post-processing on the group 13 nitride single crystal 40.

### Third Embodiment

The first embodiment describes a case in which the surrounding member 90 is a cylindrical member as an example (refer to the surrounding member 90A in FIG. 3A to FIG. 3C and the surrounding member 90B in FIG. 4A and FIG. 4B).

However, the surrounding member 90 is only required to have a shape that surrounds the entire area of the side face of the seed crystal 30 and is not limited to the cylindrical shape.

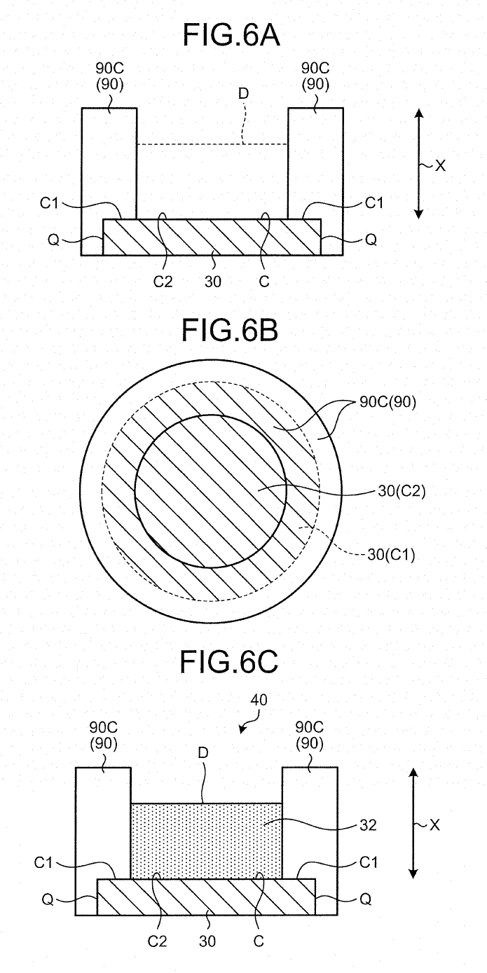

FIG. 6A to FIG. 6C are illustrative diagrams of an example of the surrounding member 90 according to the present embodiment (a surrounding member 90C). FIG. 6A is a sectional view of the seed crystal 30 and the surrounding member 90C. FIG. 6B is a top view of the seed crystal 30 and the surrounding member 90C. FIG. 6C is a sectional view illustrating a state in which the group 13 nitride crystal 32 has grown on the seed crystal 30.

As illustrated in FIG. 6A to FIG. 6C, the surrounding member 90C may be arranged so as to continuously surround the entire area of the side face Q of the seed crystal 30 and part of the principal face C of the seed crystal 30. To continuously surround them indicates that the surrounding is continuous to the extent that the mixed melt 24 does not enter between the entire area of the side face Q of the seed crystal 30 and the part of the principal face C of the seed crystal 30.

Specifically, the surrounding member 90C is arranged so as to cover the side face Q of the seed crystal 30 and an area C1 that is continuous to the side face Q and is along the periphery of the principal face C of the principal face C of the seed crystal 30. Consequently, a central area C2, which is the principal face C of the seed crystal 30 except the area C1, is not covered with the surrounding member 90C (refer to FIG. 6A and FIG. 6B).

Using the surrounding member 90C according to the present embodiment, the dissolution process and the crystal growth process are carried out similarly to the first embodiment. With this procedure, the group 13 nitride crystal 32 grows from the central area C2 that is not covered with the surrounding member 90C of the principal face C of the seed crystal 30, whereby the group 13 nitride single crystal 40 is produced as illustrated in FIG. 6C.

Consequently, it is considered that when the surrounding member 90C is used as the surrounding member 90, an effect similar to that of the first embodiment can also be obtained.

### Fourth Embodiment

The first embodiment describes a case in which the surrounding member 90 is arranged on the inside bottom B of the reaction vessel 52. However, the surrounding member 90 may be formed integrally with the bottom B of the reaction vessel 52.

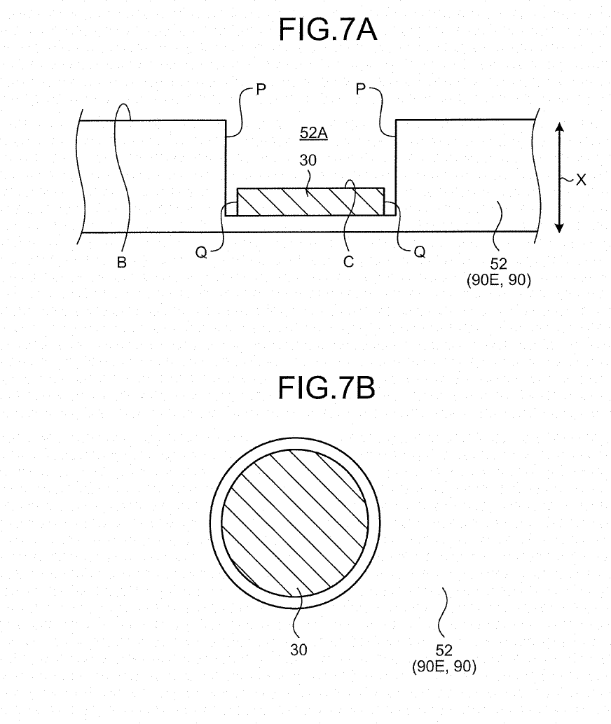

FIG. 7A and FIG. 7B are illustrative diagrams of a surrounding member 90E according to the present embodiment. FIG. 7A is a sectional view of the seed crystal 30 and the surrounding member 90E. FIG. 7B is a top view of the seed crystal 30 and the surrounding member 90E.

As illustrated in FIG. 7A and FIG. 7B, the surrounding member 90E is formed integrally with the inside bottom B of the reaction vessel 52. Specifically, a recess 52A is formed on the inside bottom B of the reaction vessel 52. In the present embodiment, the bottom B of the reaction vessel 52 having this recess 52A functions as the surrounding member 90E.

The seed crystal 30 is arranged within the recess 52A. With this arrangement, the entire area of the side face Q of the seed crystal 30 is surrounded by the inner wall of the recess 52A provided in the bottom B of the reaction vessel 52 (that is, the inner wall P of the surrounding member 90E).

Using the surrounding member 90E according to the present embodiment, the dissolution process and the crystal growth process are carried out similarly to the first embodiment. With this procedure, the group 13 nitride crystal 32 grows from the principal face C of the seed crystal 30, whereby the group 13 nitride single crystal 40 is produced.

Consequently, it is considered that when the surrounding member 90E is used as the surrounding member 90, an effect similar to that of the first embodiment can also be obtained.

The present invention is not limited to the embodiments as they are and can be embodied with the components modified without departing from the gist thereof in a practical phase. Appropriate combinations of a plurality of components disclosed in the embodiments can form various inventions. Some components may be deleted from all the components illustrated in the embodiments, for example. Furthermore, components across different embodiments may be combined as appropriate. In addition, various modifications can be made.

### EXAMPLES

The following shows examples in order to describe the present invention in more detail, but the examples do not limit the present invention. The symbols correspond to the components of the producing apparatus 1 described in the embodiments.

### Example 1

In Example 1, the group 13 single crystal 40 was produced using the producing apparatus 1.

Dissolution Process

The dissolution process was carried out by the producing apparatus 1 illustrated in FIG. 2.

A GaN crystal substrate produced by the HVPE method was prepared as the seed crystal 30. This seed crystal 30 measured 55 mm in diameter and 0.4 mm in thickness, and the surface thereof was mirror finished. The principal face of this seed crystal 30 was the c-plane, and the off angle (the angle of inclination) relative to the <0001> direction at the central part of the principal face was 0.2 degree.

The annular (ring-shaped) surrounding member 90 (refer to the surrounding member 90A in FIG. 3A to FIG. 3C) was prepared as the surrounding member 90. In other words, the inner wall P of this surrounding member 90 has a perfectly circular sectional shape.

The inner diameter of the surrounding member 90 was 56.2 mm, and the length in the first direction X of the surrounding member 90A (the first length T1) was 4 mm. A surrounding member 90 that contains AlN as a main component and 5.0% by mass of Y₂O₃ as an oxide material was used as the surrounding member 90.

The internal vessel 51 was separated from the producing apparatus 1 at the part of the valve 61 and was put into a glove box under a high-purity Ar atmosphere. Next, within the glove box, the seed crystal 30 and the surrounding member 90 were placed on the inside bottom B of the reaction vessel 52 with an inner diameter of 140 mm and a depth of 70 mm formed of alumina.

Specifically, the seed crystal 30 was arranged such that the opposite face of the principal face C of the seed crystal 30 was in contact with the center of the inside bottom B of the reaction vessel 52 and that the principal face C was directed toward the vapor-liquid interface A. The surrounding member 90 was then arranged such that the side face Q of the seed crystal 30 was surrounded by the inner wall P of the annular surrounding member 90. In this process, the surrounding member 90 was arranged such that the distance of the gap between the inner wall P of the surrounding member 90 and the side face Q of the seed crystal 30 was 0.6 mm across the 360-degree circumference about the normal line of the principal face C of the seed crystal 30.

Consequently, the end on the vapor-liquid interface A side in the first direction X of the surrounding member 90 protruded from the principal face C of the seed crystal 30 by 3.6 mm.

Next, carbon (C) and germanium (Ge) were put into the reaction vessel 52, and sodium (Na) that had been heated to be liquefied was put thereinto. After the sodium solidifies, gallium (Ga) was put thereinto.

In the present example, the molar ratio between the gallium and the sodium was set to 0.30:0.70. The carbon was set to 0.7 at % relative to the total molar number of the gallium and the sodium. The germanium was set to 2.0 at % relative to the molar number of the gallium. With this composition, the mixed melt 24 was prepared. Thus, the seed crystal 30 and the surrounding member 90 were arranged within the mixed melt 24 contained in the reaction vessel 52.

Next, the reaction vessel 52 was housed into the internal vessel 51, was taken out of the glove box, and was incorporated into the external pressure-resistant vessel 50. The reaction vessel 52 was placed on the turn table 81. The valve 61 was then closed to seal the internal vessel 51 filled with an Ar gas to isolate the inside of the reaction vessel 52 from an external atmosphere. Next, the internal vessel 51 was taken out of the glove box and was incorporated into the producing apparatus 1. Thus, the reaction vessel 52 was placed at a certain position relative to the first heating unit 70, the second heating unit 72, and the turn table 81 and was connected to the gas supply pipe 54 at the part of the valve 61.

The internal vessel 51 was mounted on the external pressure-resistant vessel 50, whereby the inside of the external pressure-resistant vessel 50 was isolated from the external atmosphere.

Next, evacuation of the inside of the pipe between the valve 61 and the valve 63 and the inside of the external pressure-resistant vessel 50 and introduction of nitrogen thereinto were repeated ten times via the valve 62. The valve 63 was closed in advance. After that, the valve 62 was closed, and the valve 61, the valve 63, and the valve 58 were opened to introduce an Ar gas from the gas supply pipe 60 for total pressure adjustment. The pressure was adjusted by the pressure control apparatus 59 to set the total pressure within the external pressure-resistant vessel 50 and the internal vessel 51 to 1.80 MPa, and the valve 58 was closed.

A nitrogen gas was introduced from the nitrogen supply pipe 57, the pressure was adjusted by the pressure control apparatus 56, the valve 55 was opened, and the total pressure within the external pressure-resistant vessel 50 and the internal vessel 51 was set to 3.43 MPa. In other words, the nitrogen partial pressure of each of the internal space 67 of the external pressure-resistant vessel 50, the internal space 68 of the internal vessel 51, and the vapor phase 22 as the internal space within the reaction vessel 52 was 1.63 MPa.

Next, the first heating unit 70 and the second heating unit 72 were energized to raise the temperature of the mixed melt 24 within the reaction vessel 52 up to a crystal growth temperature (890° C.). The nitrogen partial pressure within each of the external pressure-resistant vessel 50 and the internal vessel 51 at the crystal growth temperature was 3.8 MPa.

Crystal Growth Process

Next, the valve 55 was opened to set the nitrogen gas pressure to 8 MPa. With this process, the amount of nitrogen consumed by the crystal growth was supplied to the inside of the reaction vessel 52, and the nitrogen partial pressure can be always maintained constant. In this state, the reaction vessel 52 was held for 200 hours (with a crystal growth time of 200 hours) to grow the group 13 nitride crystal 32 on the seed crystal 30.

In the present example, while the group 13 nitride crystal 32 is growing in the crystal growth process, the mixed melt 24 was stirred. Specifically, the rotation of the turn table 81 was controlled by the controller 10 to rotate the reaction vessel 52. In this process, so as to cause relative speed between the mixed melt 24 and the seed crystal 30 during the crystal growth (that is, so as to cause a rotational speed to be different), the turn table 81 was repeatedly accelerated, rotated, decelerated, and stopped.

After the crystal growth process, the reaction vessel 52 was immersed into ethanol to wash the sodium out of the reaction vessel 52. The reaction vessel 52 after the removal of the sodium was washed with water and acid to remove the gallium and a gallium-sodium alloy. After that, the group 13 nitride single crystal 40 within the reaction vessel 52 was taken out and was washed with acid. With this process, the group 13 nitride single crystal 40 was produced.

The produced group 13 nitride single crystal 40 was a GaN single crystal. This group 13 nitride single crystal 40 measured 56.2 mm in diameter and 3.5 mm in thickness. Consequently, a subtracted value obtained by subtracting the target thickness T4 of the group 13 nitride crystal 32 grown from the third length T3 in the first direction X of the area protruding from the principal face C of the seed crystal 30 of the surrounding member 90 (refer to the subtracted value T5 in FIG. 3A to FIG. 3C) was 0.5 mm.

Evaluation

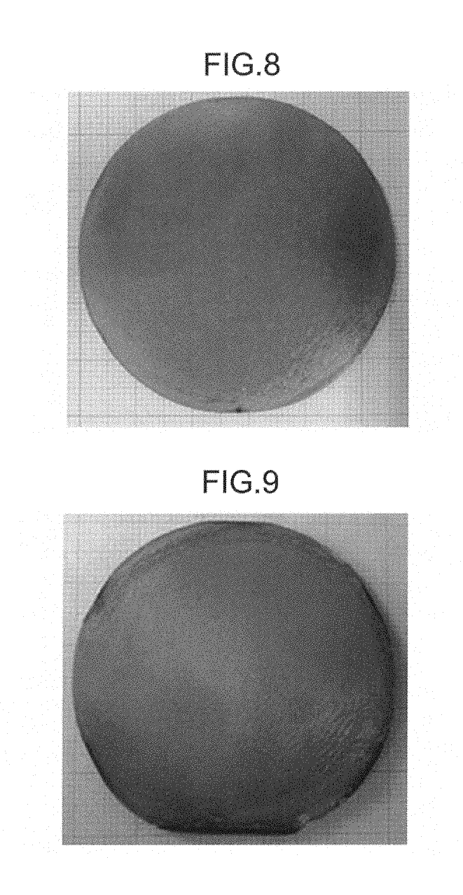

FIG. 8 illustrates the group 13 nitride single crystal 40 produced in the present example. FIG. 8 is an image obtained by photographing the group 13 nitride single crystal 40 produced in the present example from the c-plane side.

As illustrated in FIG. 8, the c-plane of the group 13 nitride single crystal 40 produced in the present example was observed, with no occurrence of cracks observed. The shape of the group 13 nitride single crystal 40 was a shape along the inner wall P of the surrounding member 90, which was cylindrical. No occurrence of crude crystals was observed on the surrounding member 90 within the reaction vessel 52. Evaluation results of crack reduction are listed in Table 1.

TABLE 1

| | Example | Example | Example | Example | Example | Example | Example | Example | Example |
|---|---|---|---|---|---|---|---|---|---|
| | 1 | 2 | 3 | 4 | 5 | 6 | 7 | 8 | 9 |
| Length of gap [mm] | 0.6 | 0 | 0.5 | 1.0 | 2.0 | 3.0 | 4.0 | 5.0 | 6.0 |
| Subtracted value T5 [mm] | 0.5 | | | | | | | | |
| (value obtained by subtracting target | | | | | | | | | |
| thickness T4 from third length T3) | | | | | | | | | |
| Main component of surrounding member | AlN | | | | | | | | |
| Material of reaction vessel | Alumina | | | | | | | | |
| Evaluation on crack reduction | 1 | 1 | 1 | 1 | 1 | 2 | 3 | 4 | 5 |

| | Example | Example | Example | Example | Example | Example | Example | Comparative |
|---|---|---|---|---|---|---|---|---|
| | 10 | 11 | 12 | 13 | 14 | 15 | 16 | Example 1 |
| Length of gap [mm] | 0.6 | 0.6 | 0.6 | 0.6 | 0.6 | 0.6 | 0.6 | — |
| Subtracted value T5 [mm] | 0.5 | | −1.5 | 10.5 | 4.5 | 0.5 | 0.5 | — |
| (value obtained by subtracting target | | | | | | | | |
| thickness T4 from third length T3) | | | | | | | | |
| Main component of surrounding member | AlN | | | | | GaN | Alumina | — |
| Material of reaction vessel | Alumina | | | | | | | |
| Evaluation on crack reduction | 1 | 1 | 4 | 3 | 2 | 4 | 4 | 5 |

In Table 1, in the evaluation on crack reduction, Evaluation “1” indicates the best evaluation (that is, cracks are the least). Evaluations “1,” “2,” “3,” “4,” and “5” are arranged in descending order of evaluation, and Evaluation “5” indicates the worst evaluation (that is, cracks are the most). The evaluation on crack reduction in this example was defined as follows based on, for five or more group 13 nitride single crystals 40 that have grown, the rate of the number of the group 13 nitride single crystals 40 in which cracks occurred.

Evaluation “1” is a crack occurrence rate of 0%;

Evaluation “2” is a crack occurrence rate of 1 to 20%;

Evaluation “3” is a crack occurrence rate of 21 to 50%;

Evaluation “4” is a crack occurrence rate of 51 to 80%; and

Evaluation “5” is a crack occurrence rate of 81 to 100%.

### Example 2 to Example 9

Surrounding members 90 with respective inner diameters of 55 mm, 56 mm, 57 mm, 59 mm, 61 mm, 63 mm, 65 mm, and 67 mm were prepared as the surrounding member 90. They are the same as the surrounding member 90 used in Example 1 except that they were different in the inner diameter.

The group 13 nitride single crystals 40 were produced on the same conditions as those of Example 1 except that these surrounding members 90 having the different inner diameters were used in place of the surrounding member 90 used in Example 1.

These surrounding members 90 having the different inner diameters were used, whereby the respective group 13 nitride single crystals 40 were produced as Example 2 to Example 9 when the respective distances of the gaps between the inner wall P of the surrounding member 90 and the side face Q of the seed crystal 30 were 0 mm, 0.5 mm, 1.0 mm, 2.0 mm, 3.0 mm, 4.0 mm, 5.0 mm, and 6.0 mm. As to the surrounding member with a gap of 0 mm of Example 2, considering that the GaN crystal expands by about 50 μm based on a difference in the coefficient of thermal expansion between GaN and AlN at a crystal growth temperature of 890° C., the surrounding member with an inner diameter of 55 mm produced with a tolerance of +0.06 to +0.10 mm was used (a diameter of 55.06 to 55.1 mm).

Evaluation

The group 13 nitride single crystals 40 produced in Example 2 to Example 9 were GaN single crystals. These group 13 nitride single crystals 40 measured 3.5 mm in thickness. Consequently, the subtracted value obtained by subtracting the target thickness T4 of the group 13 nitride crystal 32 grown from the third length T3 in the first direction X of the area protruding from the principal face C of the seed crystal 30 of the surrounding member 90 (refer to the subtracted value T5 in FIG. 3A to FIG. 3C) was 0.5 mm for all Example 2 to Example 9.

For each of the group 13 nitride single crystals 40 produced in Example 2 to Example 9, the c-plane was observed to observe the presence or absence of the occurrence of cracks.

For Example 2 to Example 5 in which the distance of the gap was shorter than 3 mm, the formation of the {10-11} plane was not observed, and no cracks occurred similarly to Example 1.

In contrast, for Example 6 and Example 7 in which the distance of the gap was 3 mm or longer and shorter than 5 mm, the formation of the {10-11} plane was observed, although being less than that of Example 8, and more cracks than those of Example 2 to Example 5 occurred, although being less than those of Example 8. For Example 8 in which the distance of the gap was 5 mm, more cracks than those of Example 7 occurred, although being less in the formation of the {10-11} plane and cracks than a comparative example described below. Furthermore, for Example 9 in which the distance of the gap was 6 mm, the formation of the {10-11} plane and the occurrence of cracks were observed on the same level with the comparative example described below. Evaluation results of crack reduction are listed in Table 1.

### Example 10

A surrounding member 90 that has an annular shape (ring shape) and of which the shape represented by the inner wall P of a section in a direction orthogonal to the first direction X is a shape in which part of the outer circumference of a perfect circle is represented by a linear side was prepared as the surrounding member 90. The surrounding member 90 prepared in the present example was the same surrounding member 90 as that of Example 1 except that the shape of the inner wall P was different. The distance of the gap between the inner wall P of the surrounding member 90 and the side face Q of the seed crystal 30 and the like are also the same as those of Example 1.

The group 13 nitride single crystal 40 was produced on the same conditions as those of Example 1 except that the surrounding member 90 prepared in the present example was used in place of the surrounding member 90 used in Example 1.

Evaluation

The group 13 nitride single crystal 40 produced in the present example was a GaN single crystal. This group 13 nitride single crystal 40 measured 56.2 mm in diameter and 3.5 mm in thickness. Consequently, the subtracted value obtained by subtracting the target thickness T4 of the group 13 nitride crystal 32 grown from the third length T3 in the first direction X of the area protruding from the principal face C of the seed crystal 30 of the surrounding member 90 (refer to the subtracted value T5 in FIG. 3A to FIG. 3C) was 0.5 mm.

FIG. 9 illustrates the group 13 nitride single crystal 40 produced in the present example. FIG. 9 is an image obtained by photographing the group 13 nitride single crystal 40 produced in the present example from the c-plane side.

As illustrated in FIG. 9, the c-plane of the group 13 nitride single crystal 40 produced in the present example was observed, with no occurrence of cracks observed. The shape of the group 13 nitride single crystal 40 was a shape along the inner wall P of the surrounding member 90, which was a shape formed with orientation flat. No occurrence of crude crystals was observed on the surrounding member 90 within the reaction vessel 52. Evaluation results of crack reduction are listed in Table 1.

### Example 11

A new surrounding member 90 including the annular (ring-shaped) surrounding member 90 used in Example 1 (refer to the surrounding member 90A in FIG. 3A to FIG. 3C) and a surrounding member 90 the outer wall of which is arranged in contact with the inside (the inner wall P side) of the surrounding member 90 was prepared as the surrounding member 90.

The inner diameter of the surrounding member 90 arranged inside the surrounding member 90 used in Example 1 was 51 mm, and the surrounding member 90 was arranged such that the vapor-liquid interface A side end of the surrounding member 90 coincided with the vapor-liquid interface A side end of the outer surrounding member 90 and that the bottom B side end thereof was in contact with the c-plane of the seed crystal 30. With this arrangement, the outer surrounding member 90 surrounded the entire area of the side face Q of the seed crystal 30, whereas the inner surrounding member 90 covered the area C1 that is a partial area of the principal face C of the seed crystal 30 and is along the periphery of the principal face C. As to the principal face C of the seed crystal 30, an area with a width of 2 mm toward the center of the principal face C from the periphery of the principal face C was covered with the surrounding member 90 of the present example.

The group 13 nitride single crystal 40 was produced on the same conditions as those of Example 1 except that the surrounding member 90 prepared in the present example was used in place of the surrounding member 90 used in Example 1.

Evaluation

The group 13 nitride single crystal 40 produced in the present example was a GaN single crystal. This group 13 nitride single crystal 40 measured 51 mm in diameter, which was smaller than the diameter of the seed crystal 30, and 3.5 mm in thickness. The subtracted value obtained by subtracting the target thickness T4 of the group 13 nitride crystal 32 grown from the third length T3 in the first direction X of the area protruding from the principal face C of the seed crystal 30 of the surrounding member 90 (refer to the subtracted value T5 in FIG. 3A to FIG. 3C) was 0.5 mm.

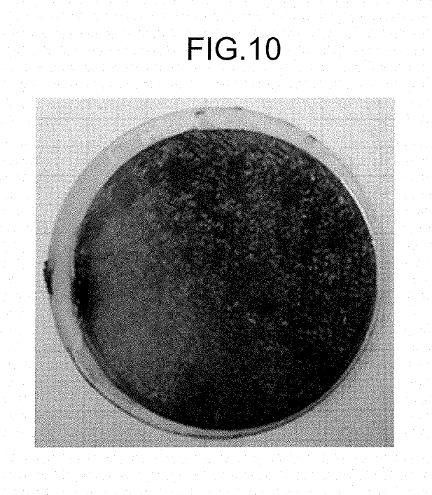

FIG. 10 illustrates the group 13 nitride single crystal 40 produced in the present example. FIG. 10 is an image obtained by photographing the group 13 nitride single crystal 40 produced in the present example from the c-plane side.

As illustrated in FIG. 10, the c-plane of the group 13 nitride single crystal 40 produced in the present example was observed, with no occurrence of cracks observed. The shape of the group 13 nitride single crystal 40 was a shape (cylindrical) along the inner wall P of the inner surrounding member 90 used in the present example. No occurrence of crude crystals was observed on the surrounding member 90 within the reaction vessel 52. Evaluation results of crack reduction are listed in Table 1.

### Example 12

The group 13 nitride single crystal 40 was produced on the same conditions of Example 1 except that a surrounding member 90 with a height in the first direction X (a first length T1) of 2 mm was used.

Evaluation

The produced group 13 nitride single crystal 40 was a GaN single crystal. This group 13 nitride single crystal 40 measured 56.2 mm in diameter and 3.5 mm in thickness. Consequently, the subtracted value obtained by subtracting the target thickness T4 of the group 13 nitride crystal 32 grown from the third length T3 in the first direction X of the area protruding from the principal face C of the seed crystal 30 of the surrounding member 90 (refer to the subtracted value T5 in FIG. 3A to FIG. 3C) was −1.5 mm.

An area that had been surrounded by the surrounding member 90 of the group 13 nitride single crystal 40 was cylindrical with a diameter of 56.2 mm similarly to the shape of the inner wall P of the surrounding member 90. In the area that had been surrounded by the surrounding member 90 of the group 13 nitride single crystal 40, no occurrence of cracks was observed. In contrast, an area that had been exposed out of the surrounding member 90 was hexagonal, and the {10-11} plane was formed across the entire circumference of the c-plane, with the occurrence of cracks observed. Consequently, although the occurrence of cracks was reduced compared with the comparative example described below, the effect of crack reduction was lower than that of Example 1. Evaluation results are listed in Table 1.

### Example 13 and Example 14

The group 13 nitride single crystals 40 with a thickness of 3.5 mm were produced on the same conditions as those of Example 1 except that surrounding members 90 with respective heights in the first direction X (first lengths T1) of 14 mm and 8 mm were used. Consequently, the subtracted values obtained by subtracting the target thickness T4 of the group 13 nitride crystal 32 grown from the third length T3 in the first direction X of the area protruding from the principal face C of the seed crystal 30 of the surrounding member 90 (refer to the subtracted value T5 in FIG. 3A to FIG. 3C) were each 10.5 mm and 4.5 mm.

Evaluation

The produced group 13 nitride single crystal 40 was a GaN single crystal with a diameter of 56.2 mm and a thickness of 3.5 mm.

In the group 13 nitride single crystal 40 of Example 13 (an example using the surrounding member 90 with a first length T1 of 14 mm), in the majority of cases, polycrystallization occurred during the growth or a large amount of inclusions were taken in, although being less in the occurrence of cracks than the comparative example described below, and most of them were unusable crystals. In addition, some cracks occurred from a polycrystallized area. Evaluation results of crack reduction are listed in Table 1.

In the group 13 nitride single crystal 40 of Example 14 (an example using the surrounding member 90 with a first length T1 of 8 mm), less cracks occurred than the comparative example described below, and no polycrystallization was observed. However, in the group 13 nitride single crystal 40 of Example 14, the occurrence of more cracks and a larger take-in amount of inclusions near the outer circumference of the c-plane were observed than those of Example 1. Evaluation results of crack reduction are listed in Table 1.

### Example 15

The group 13 nitride single crystal 40 was produced on the same conditions as those of Example 1 except that a surrounding member 90 formed of GaN was used as the surrounding members 90.

Evaluation

The group 13 nitride single crystal 40 produced in the present example was a GaN single crystal with a thickness of 3.5 mm and with a hexagonal outer circumference. The group 13 nitride single crystal 40 of the present example grew integrally with the surrounding member 90. In addition, in the group 13 nitride single crystal 40 of the present example, more cracks than those of Example 1 occurred, although being less in the occurrence of cracks than the comparative example described below, and a {10-11} growth area was formed across the entire circumference on the side face of the group 13 nitride single crystal 40. Evaluation results of crack reduction are listed in Table 1.

### Example 16

The group 13 nitride single crystal 40 was produced on the same conditions as those of Example 1 except that a surrounding member 90 formed of alumina (Al₂O₃) was used as the surrounding member 90.

The coefficient of thermal expansion of a GaN crystal is 5.6×10⁻⁶/K, the coefficient of thermal expansion of an alumina (Al₂O₃) sintered body is 7.7×10⁻⁶/K, and the coefficient of thermal expansion of an AlN sintered body is 4.5×10⁻⁶/K.

Evaluation

The produced group 13 nitride single crystal 40 was a GaN single crystal with a diameter of 56.2 mm and a thickness of 3.5 mm. In the group 13 nitride single crystal 40 of the present example, more cracks than those of Example 1 occurred, although being less in the occurrence of cracks than the comparative example described below. In the group 13 nitride single crystal 40 of the present example, the formation of the {10-11} plane was not observed. Evaluation results of crack reduction are listed in Table 1.

### Comparative Example 1

The group 13 nitride single crystal 41 was produced similarly to Example 1 except that the surrounding member 90 was not used.

Evaluation

The produced group 13 nitride single crystal 41 was a GaN single crystal with a thickness of 3.5 mm.

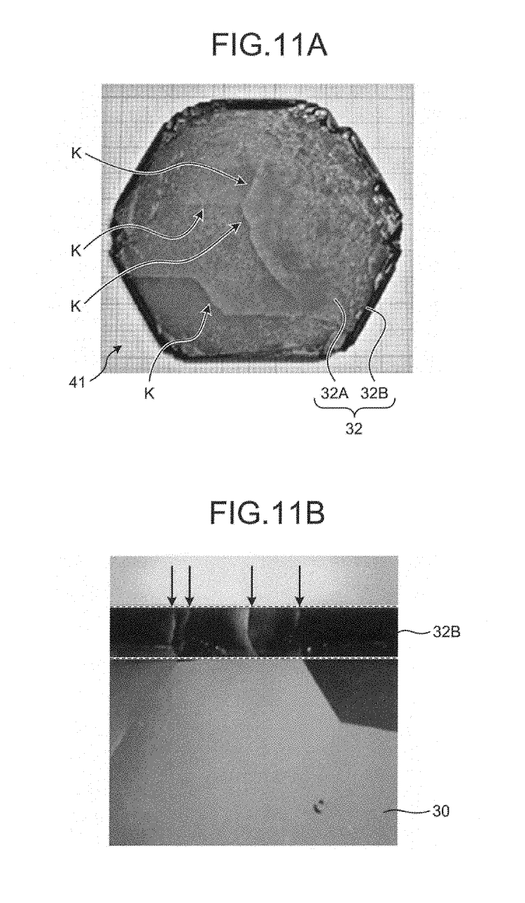

FIG. 11A and FIG. 11B are photographed images of the group 13 nitride single crystal 41 produced in the present comparative example. FIG. 11A is an image obtained by photographing the produced group 13 nitride single crystal 41 from the c-plane side. FIG. 11B is an image obtained by photographing the vicinity of an end face of the group 13 nitride single crystal 41 produced in the present comparative example from the −c-plane side.

As illustrated in FIG. 11A and FIG. 11B, in the group 13 nitride single crystal 41 produced in the present comparative example, the largest number of cracks was observed compared with those of the examples. The {10-11} plane was formed across the entire circumference of the hexagonal group 13 nitride single crystal 41 (refer to the cracks K in FIG. 11A and FIG. 11B).

The number of cracks that occurred was larger than that of any of the examples, and Evaluation “5”, which was the worst, was given for that in the evaluation on crack reduction (refer to Table 1).

As illustrated in FIG. 11B, in the group 13 nitride single crystal 41 produced in the comparative example, many cracks occurred in the {10-11} growth area 32B. In addition, observed in the group 13 nitride single crystal 41 was propagation of cracks from the {10-11} growth area 32B to the c-plane growth area 32A. Consequently, it was able to infer that the {10-11} growth area 32B caused the occurrence of the cracks.

For the group 13 nitride single crystal 41 produced in the comparative example, the lattice constants of the c-plane growth area 32A and the {10-11} growth area 32B were measured; the lattice constants of the c-plane growth area 32A were 5.1849 Å (5.1849×10⁻¹⁰ m) for the c-axial direction and 3.1881 Å for the a-axial direction, whereas the lattice constants of the {10-11} growth area 32B were 5.1857 Å for the c-axial direction and 3.1882 Å for the a-axial direction. The {10-11} growth area 32B was larger than the c-plane growth area 32A both for the c-axial direction and the a-axial direction.

For the group 13 nitride single crystal 41 produced in the present comparative example, the oxygen concentrations of the c-plane growth area 32A and the {10-11} growth area 32B were measured by secondary ion mass spectrometry (SIMS). The oxygen concentration of the c-plane growth area 32A was 2×10¹⁷ cm⁻³, whereas the oxygen concentration of the {10-11} growth area 32B was 5×10¹⁹ cm⁻³.

Consequently, in the group 13 nitride single crystal 41 produced in the present comparative example, it is inferred that the difference in oxygen concentration between the c-plane growth area 32A and the {10-11} growth area 32B caused the difference in the lattice constants, which introduced strain into the crystal. Consequently, it is considered that more cracks occurred in the group 13 nitride single crystal 41 produced in the present comparative example than in any of the group 13 nitride single crystals 40 produced in the examples (Example 1 to Example 16).

In contrast, the group 13 nitride single crystals 40 produced in the examples (Example 1 to Example 16) effectively reduced the occurrence of cracks compared with the group 13 nitride single crystal 41 produced in the comparative example as listed in Table 1, and more favorable evaluations were given for them than that for the comparative example in the evaluation on crack reduction.

It could be inferred that this was because in the group 13 nitride single crystals 40 produced in the examples (Example 1 to Example 16), the {10-11} growth of the group 13 nitride crystal 32 that grows from the seed crystal 30 was inhibited by the surrounding member 90.

The present invention can reduce cracks.

The above-described embodiments are illustrative and do not limit the present invention. Thus, numerous additional modifications and variations are possible in light of the above teachings. For example, at least one element of different illustrative and exemplary embodiments herein may be combined with each other or substituted for each other within the scope of this disclosure and appended claims. Further, features of components of the embodiments, such as the number, the position, and the shape are not limited the embodiments and thus may be preferably set. It is therefore to be understood that within the scope of the appended claims, the disclosure of the present invention may be practiced otherwise than as specifically described herein.

The method steps, processes, or operations described herein are not to be construed as necessarily requiring their performance in the particular order discussed or illustrated, unless specifically identified as an order of performance or clearly identified through the context. It is also to be understood that additional or alternative steps may be employed.

What is claimed is:

1. A method for producing a group 13 nitride single crystal, the method comprising:
dissolving nitrogen in a mixed melt containing an alkali metal and a group 13 metal in a reaction vessel, the reaction vessel containing
the mixed melt,
a seed crystal that is placed in the mixed melt and includes a group 13 nitride crystal in which a principal face is a c-plane, and
a surrounding member arranged so as to surround an entire area of a side face of the seed crystal; and
growing a group 13 nitride crystal on the seed crystal.

2. The method for producing a group 13 nitride single crystal according to claim 1, wherein a distance of a gap between the side face of the seed crystal and the surrounding member is shorter than 5 mm.

3. The method for producing a group 13 nitride single crystal according to claim 1, wherein a distance of a gap between the side face of the seed crystal and the surrounding member is shorter than 2 mm.

4. The method for producing a group 13 nitride single crystal according to claim 1, wherein the surrounding member is arranged in contact with the side face of the seed crystal.

5. The method for producing a group 13 nitride single crystal according to claim 1, wherein the surrounding member is arranged so as to continuously surround the entire area of the side face of the seed crystal and part of the principal face.

6. The method for producing a group 13 nitride single crystal according to claim 1, wherein
the surrounding member is an inside bottom of the reaction vessel having a recess opening toward a vapor-liquid interface between the mixed melt contained in the reaction vessel and a vapor phase, and
the seed crystal is arranged within the recess such that the entire area of the side face of the seed crystal is surrounded by the surrounding member.

7. The method for producing a group 13 nitride single crystal according to claim 1, wherein
a first length of the surrounding member in a first direction orthogonal to the principal face is longer than a second length in the first direction of the seed crystal, and
the surrounding member is arranged such that one end in the first direction of the surrounding member protrudes from the principal face of the seed crystal toward a vapor-liquid interface between the mixed melt and a vapor phase.

8. The method for producing a group 13 nitride single crystal according to claim 7, wherein a third length in the first direction of an area in the surrounding member protruding from the principal face toward the vapor-liquid interface is longer than a target thickness set in advance of the group 13 nitride crystal grown on the principal face.

9. The method for producing a group 13 nitride single crystal according to claim 1, wherein the surrounding member and the group 13 nitride crystal grown on the seed crystal have different main components.

10. The method for producing a group 13 nitride single crystal according to claim 1, wherein a coefficient of thermal expansion of the surrounding member is smaller than a coefficient of thermal expansion of the group 13 nitride crystal grown on the seed crystal.

11. The method for producing a group 13 nitride single crystal according to claim 1, wherein the reaction vessel contains an oxide material.

12. An apparatus for producing a group 13 nitride single crystal by a flux method, the apparatus comprising:
a reaction vessel containing
a mixed melt containing an alkali metal and a group 13 metal,
a seed crystal that is placed in the mixed melt and includes a group 13 nitride crystal in which a principal face is a c-plane, and
a surrounding member arranged so as to surround an entire area of a side face of the seed crystal.
